(19) United States
(12) Patent Application Publication
(10) Pub. No.: US 2006/0170444 A1
(43) Pub. Date: Aug. 3, 2006

(54) Novel fluorescent and photoemission apparatus and method for submicron IC failure analysis

(76) Inventors: Zong Min Wu, Camas, WA (US); Chong Khiam Oh, Singapore (SG); Lip Sin Cheong, Singapore (SG); Shailesh Redkar, Singapore (SG)

Correspondence Address: WAGNER, MURABITO & HAO LLP, Third Floor, Two North Market Street, San Jose, CA, 95113, US

(21) Appl. No.: 11/049,337

(22) Filed: Feb. 2, 2005

(51) Int. Cl. G01R 31/26

(52) U.S. Cl. 324/765

(57) ABSTRACT

A single integrated fault detection apparatus and method for detecting heat-related and non-heat-related integrated circuit defects is disclosed. In one embodiment, the present invention is an apparatus comprising a first portion for detecting non-heat-related integrated circuit defects. In this embodiment, the present invention further comprises a second portion for detecting heat-related integrated circuit defects. In the present embodiment, the second portion is integrated with the first portion to provide a single integrated fault detection apparatus such that the heat-related and the non-heat-related integrated circuit defects are detectable using only a single integrated fault detection apparatus.

### FIELD OF THE INVENTION

The present claimed invention relates to the field of semiconductor device fabrication and processing. More particularly, the present claimed invention relates to a method and apparatus for failure analysis of integrated circuits.

### BACKGROUND ART

Photoemission microscopy (PEM) has been widely used in modern integrated circuit (IC) failure analysis. Due to physical limitations of the camera/detector of a conventional PEM system, such prior art systems normally only detect optical emissions with wavelengths ranging approximately from visible to near infrared. Therefore, conventional PEM systems are more sensitive to non-heat-related integrated circuit failures such as, for example, junction related defects, gate oxide related defects, etc.

As a complimentary technique, infrared photoemission microscopy (IRPEM) was developed by different companies and/or failure analysis laboratories to deal with heat-related defect isolation. However, the spatial resolution of IRPEM is limited by the wavelength of the infrared light IRPEM uses. More specifically, because the infrared array of a conventional IRPEM system has a 1.5 micron to 12 micron spectral response, the spatial resolution for long wavelengths is poor. Such a limitation is especially disadvantageous as the critical dimensions of integrated circuit (IC) features shrink toward to 1 micron and smaller.

In yet another prior art approach, liquid crystal (LC) analysis has been employed as an economical failure analysis technique. LC analysis has been used with great success for hot spot detection during IC failure analysis since the 1980's. However, due to its binary thermal response, LC analysis does not provide crucial information related to the thermal distribution generated by the defect. Moreover, the thermal sensitivity of LC analysis is also limited by the reduction in device operating voltage associated with deep submicron technology ICs.

Due to the respective limitations (e.g. insufficient spatial and thermal resolution) of various prior art systems, IC failure analysis is sometimes performed using multiple separate conventional systems. As an example, failure analysis is first performed on an IC using a conventional PEM system in order to detect a non-heat-related IC failure such as, for example, a junction related defect, a gate oxide related defect, etc. Next, the same IC is then subjected to further failure analysis using a conventional LC analysis system to scan, for example, for hot spots. The use of multiple discrete systems (e.g. at least two separate failure analysis systems) has significant disadvantages including inconvenience, substantial cost, reduced throughput, and the like, associated therewith.

Thus, a need exists for a method and apparatus for performing failure analysis on an integrated circuit with submicron critical dimensions more efficiently. A further need exists for a method and apparatus which meet the above need and which can perform failure analysis for both heat-related and non-heat-related defects on an integrated circuit without requiring the use of multiple separate failure analysis systems. Still another need exists for a method and apparatus for performing failure analysis on an integrated circuit wherein the method and apparatus meet the above needs and do not result in the reduced throughput and accuracy associated with prior art approaches employing multiple separate conventional failure analysis systems.

### SUMMARY OF INVENTION

The present invention provides a method and apparatus for performing failure analysis on an integrated circuit with submicron critical dimensions more efficiently. The present invention also provides a method and apparatus which achieve the above accomplishment and which can perform failure analysis for both heat-related and non-heat-related defects on an integrated circuit without requiring the use of multiple separate failure analysis systems. The present invention further provides a method and apparatus for performing failure analysis on an integrated circuit wherein the method and apparatus achieve the above accomplishments and do not result in the reduced throughput and accuracy associated with prior art approaches employing multiple separate conventional failure analysis systems.

In one embodiment, the present invention is an apparatus comprising a first portion for detecting non-heat-related integrated circuit defects. In this embodiment, the present invention further comprises a second portion for detecting heat-related integrated circuit defects. In the present embodiment, the second portion is integrated with the first portion to provide a single integrated fault detection apparatus such that the heat-related and the non-heat-related integrated circuit defects are detectable using only a single integrated fault detection apparatus without sacrificing the accuracy of each portion comparing the separate approaches.

These and other objects and advantages of the present invention will no doubt become obvious to those of ordinary skill in the art after having read the following detailed description of the preferred embodiments which are illustrated in the various drawing figures.

### BRIEF DESCRIPTION OF THE DRAWINGS

The accompanying drawings, which are incorporated in and form a part of this specification, illustrates embodiments of the invention and, together with the description, serve to explain the principles of the invention:

FIG. 1 is a schematic view of an FPEM system in accordance with one embodiment of the present claimed invention.

FIG. 2 is a flow chart of steps performed in accordance with one embodiment of the present claimed invention.

The drawings referred to in this description should be understood as not being drawn to scale except if specifically noted.

### DESCRIPTION OF THE PREFERRED EMBODIMENTS

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well known methods, procedures, components, and circuits have not been described in detail as not to unnecessarily obscure aspects of the present invention.

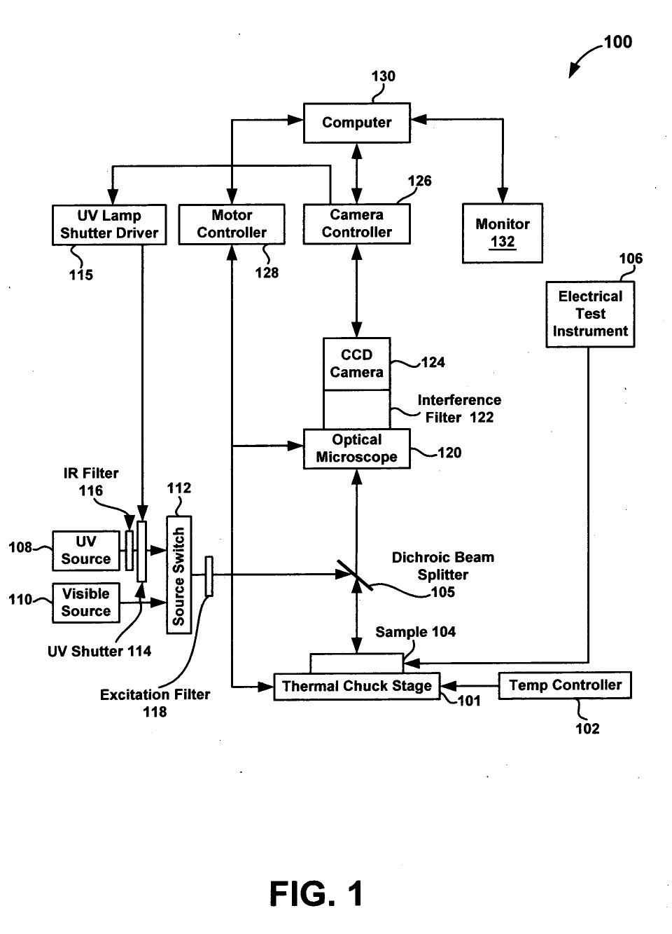

With reference now to FIG. 1, a schematic view of a fluorescent and photoemission microscope (FPEM) system 100 in accordance with one embodiment of the present claimed invention is shown. In the present invention, the novel FPEM system 100 uses only one visible light slow-scan CCD camera 124 to detect both heat-related and non-heat-related defects at higher spatial resolution and thermal sensitivity than has been possible with conventional systems. The present detailed description will begin with a discussion of the physical structure of the present FPEM system 100. The present detailed description will then be followed by a discussion of the operation of the present FPEM system 100.

Physical Structure of the Present FPEM System

The present FPEM system 100 is well suited for submicron and deep submicron ULSI (Ultra Large Structure Integrated Circuit) and VLSI (Very Large Structure Integrated Circuit) failure analysis. Unlike conventional approaches which employ multiple systems such as, for example, a PEM system to detect non-heat-related defects and a separate LC system or IRPEM system to detect heat-related defects independently, the present FPEM system 100 is able to perform multiple kinds of fault isolations (e.g. heat-related and non-heat-related) for failure analysis with one common hardware setup. Hence, the present FPEM system 100 eliminates the need for multiple separate failure analysis systems. Hence, the present FPEM system 100 does not suffer from the reduced throughput associated with prior art approaches employing multiple separate conventional failure analysis systems.

With reference still to FIG. 1, as an overview, FPEM system 100 includes PEM components and also provides an effective isolation technique for the heat-related defect detection. Furthermore, FPEM system 100 has higher spatial resolution than conventional IRPEM systems and better thermal sensitivity than LC techniques. One key advantage of the present FPEM system 100 is that with only one slow-scan CCD camera, FPEM system 100 detects defects whether they are heat or non-heat related. FPEM system 100 also provides for measuring of the temperature profile originating from the defect. That is, FPEM system 100 allows users to perform fault isolation on both heat and non-heat related failures in one system, thereby saving time as compared to conventional separate systems.

With reference still to FIG. 1 and FPEM system 100, the PEM portion of the present invention was developed because it amplifies low level photon emission in biased semiconductors through a process of amplification, integration, and image processing. The basis is PEM is the detection of weak (often 6-8 orders of magnitude lower than the human eye can detect) photon emissions from the surface of a biased integrated circuit. A photon is the light emitted when two different species of charged particles meet in a semiconductor. The source in a semiconductor is electron flow (−) and the production of holes (+) which both migrate to the PN junction in a semiconductor environment. The on-rushing electrons collide with the holes resulting in the release of a photon. This process is also called electron-hole pair recombination. Such recombination can be explained by two mechanisms, those mechanisms are interband recombination and intraband recombination. Interband recombination is an allowable transition of the electron from the conduction band to an open energy state in the valence band. When the transition occurs, a photon is emitted. Intraband recombination occurs as the energy band for holes in silicon is actually two bands representing light and heavy holes, during dynamic conditions, with hole current present, transitions occur between these bands providing photons of low energy (<1.0 eV).

With reference still to FIG. 1 and FPEM system 100, the FMI (fluorescent microthermal imaging) portion of the present invention provides the ability to create thermal maps of integrated circuits with a thermal resolution theoretically limited to 0.001° C., and a spatial resolution that is diffraction-limited to 0.3 microns. While the temperature resolution is comparable to that available on IR systems, the spatial resolution is much better. The FMI technique of the present FPEM system 100 provides improved spatial resolution by imaging of a temperature-dependent fluorescence at 612 nanometers instead of the 1.5 to 12 micron emission ranges used by IR techniques. The FMI technique of the present FPEM system involves coating a sample IC surface with a fluorescent rare-earth-based thin film (e.g. europium thenoyltrifluoracetonate referred as EuTTA) that, upon exposure to UV light, emits temperature-dependent fluorescence. In the present embodiment, EuTTA is used because of its temperature characteristics, emission/absorption characteristics, availability, and other qualities. More specifically, EuTTA has the best fit for temperature-dependent fluorescence quantum yield in the temperature range near room temperature. That is, compared to a conventional LC technique, the FMI technique of the present FPEM system 100 provides more accurate isolation of hot spots with clear and precise imaging.

Referring still to FIG. 1, the present FPEM system is comprised of a thermal chuck stage 101 which is adapted to have a sample 104 coupled thereto. An electrical test instrument 106 is also coupled to sample 104. Thermal chuck stage 101 is further coupled to a temperature controller 102 and to a motor controller 128. FPEM system 100 of the present embodiment also includes an ultraviolet light source 108 and a visible source 110. The ultraviolet light source 108 and the visible source 110 are both directed towards a dichroic beam splitter 105. An IR filter 116, an ultraviolet shutter 114, and a source switch 112 are disposed between ultraviolet source 108 and dichroic beam splitter 105. Source switch 112 is also disposed between visible source 110 and dichroic beam splitter 105. Additionally, a UV lamp shutter driver 115 is coupled to UV shutter 114. For purposes of the present application, UV source 108, visible source 110, IR filter 116, excitation filter 118, UV shutter 114, source switch 112, UV lamp shutter driver 115, dichroic beam splitter 105, and interference filter 122 comprise a “switchable light source portion”.

With reference still to FIG. 1, in the present FPEM system 100, in addition to being coupled to thermal chuck stage 101, motor controller 128 is also coupled to computer 130 and to optical microscope 120. In the present embodiment computer 130 is coupled to camera controller 126 and to monitor 132. As shown in FPEM system 100 of FIG. 1, camera controller 126 is also coupled to both UV lamp shutter driver 115 and to CCD camera 124. For purposes of the present application, CCD camera 124 and optical microscope 120 comprise an “optical inspection portion”. Furthermore, for purposes of the present application, computer 130, camera controller 126, and motor controller 128 comprise a “controller portion”. Also, for purposes of the present application, computer 130 and monitor 132 comprise a “monitoring portion”.

Referring again to FIG. 1, in FPEM system 100, an interference filter 122 is coupled between optical microscope 120 and CCD camera 124. Optical microscope 120 is disposed to selectively receive optical signals from sample 104, from visible source 110, and from UV source 108. As shown in FPEM system 100 of FIG. 1, dichroic beam splitter 105 is disposed between UV source 108, visible source 110, sample 104, and optical microscope 120. Although such specific components and configurations are recited in the present embodiment, the present invention is well suited to varying the number and type of components as well as the configuration of the components. More important than the specific arrangement and type of elements, the present invention is comprised of a single integrated system (i.e. FPEM system 100) which allows users to perform fault isolation on both heat and non-heat related failures in one system, thereby saving time as compared to conventional separate fault detection systems. The following detailed description will now discuss operation of the present FPEM system 100.

In Operation

In this system, the principle and method of PEM is used to analyze non-heat related failures/defects. For the heat-related defeats, the present FPEM system 100 uses a chemical film which is applied to sample 104 to detect the heat related defect using a fluorescent microthermal imaging technique. In one embodiment, the chemical film is a mixture of EuTTA, PMMA (polymethylmethacrylate) and MEK (methylethylketone). When subjected to UV light excitation from UV source 108 (as regulated by UV shutter 114 and source switch 112, and as filtered by IR filter 116 and excitation filter 118), the chemical film converts the heat generated by the defects on sample 104 to the fluorescent light of a peak at about 612 nanometers. In the present embodiment, the UV light is direct towards sample 104 by dichroic beam splitter 105. This kind of film is transparent inherently and is coated onto the surface of sample 104 using a photoresist spinner. A thinner and more uniform layer typically generates better results. As photoemission can penetrate such a transparent film without attenuation, it is suggested that sample 104 be coated with film before analysis is both isolation are performed. It is noted that attention should be paid to overdrive a bit in order to achieve reliable contact between probe tips and bondpads during probing on wafer level sample.

With reference still to FIG. 1, the generated fluorescent light having a peak energy of about 612 nanometers is detected by the slow-scan CCD camera 124. In the present embodiment, slow-scan CCD camera 124 is the common detector to capture both photoemission and fluorescent signals. In one embodiment of the present invention, a 16 bit slow-scan CCD camera is employed to ensure the sensitivity of FPEM system 100.

More specifically, during operation of the present FPEM system 100, both PEM and FMI processes are employed in a single integrated system (i.e. FPEM system 100) to detect both heat-related and non-heat-related defects. As mentioned above, during operation, UV source 108 is used for fluorescent excitation. Computer 130 in conjunction with motor controller 128 and camera controller 126 controls the movements of thermal chuck stage 101 and also optical microscope 120, respectively. That is, during PEM mode, source switch 112 blocks the UV light from UV source 108 (e.g. prevents transmission thereof) and allows the visible light from visible source 110 to pass therethrough for normal imaging. Both interference filter 122 and excitation filter 118 are pulled out for normal visible light imaging such an ensure the full range of optical emissions reach CCD camera 124. Furthermore, during the PEM mode, dichroic beam splitter 105 is replaced by a normal optical mirror (not shown) to reflect the visible light from visible source 110 onto sample 104 (for normal imaging), and to also allow the photoemission to pass through and reach CCD camera 124 (for photoemission detection).

Continuing with the discussion of the operation of FPEM system 100, during the FMI mode, visible light source 110 is utilized to get the normal image for overlay purpose. After obtaining the image for overlay purposes, the present embodiment, adjusts source switch 112 such that it passes only UV light and blocks visible light. When in FMI mode, FPEM system 100 inserts IR filter 116, excitation filter 118, interference filter 122, and dichroic beam splitter 105 into the optical path to ensure that sufficient UV excitation and to ensure that only the fluorescence of 612 nanometers reaches CCD camera 124. More specifically, IR filter 116 is used to block heat from UV source 108. Excitation filter 118 allows only UV light (cut off at 390 nanometers) to pass through. Interference filter 122 is used to ensure that CCD camera 124 receives only the fluorescent light of approximately 612 nanometer wavelength. As to dichroic beam splitter 105, it reflects as much UV light as possible onto the surface of sample 104 and meanwhile allows as much fluorescence as is possible to be transmitted to CCD camera 124. Furthermore, during FMI mode, UV shutter 114 of FPEM system 100 is synchronized with the shutter (not shown) of CCD camera 124 to avoid extended exposure of the fluorescent film (not shown) of sample 104 to UV light. As a result, FPEM system 100 of the present embodiment prevents potential film “bleaching”.

Referring still to the operation of FPEM system 100, the final photoemission and/or fluorescent microthermal images are processed by computer 130 and are then available to be displayed on monitor 132 in real time. After such images are obtained, those images can then be overlaid onto a normal optical image for defect localization. Additionally, FPEM system 100 allows all of the images to be saved into, for example, the hard disk (not shown) of computer 130 or onto various other storage media in any of various formats. Also, in FPEM system 100, temperature controller 102 is used to maintain sample 104, via thermal chuck stage 101, at a desired temperature. In one embodiment, FPEM system 100 includes electrical test instrument 106 which is used to bias sample 104 (device) electrically upon the applicable bench test setup. This is to analyze the device at its failing condition.

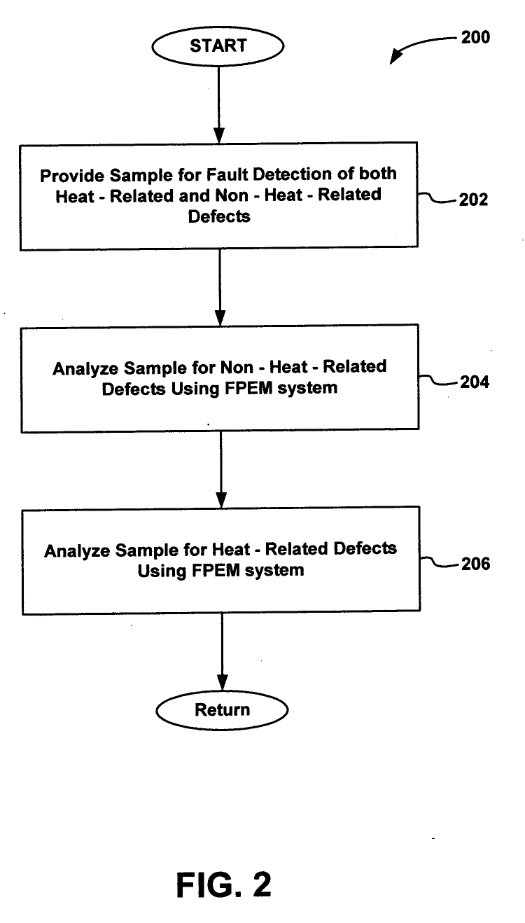

With reference now to FIG. 2, a flow chart of steps performed in accordance with one embodiment of the present invention is shown. In step 202, the present embodiment provides a sample (e.g. an integrated circuit) for fault detection of both heat-related and non-heat-related defects. As mentioned above, in one embodiment, the present invention applies a chemical film to the sample to detect the heat related defects via a fluorescent microthermal imaging technique. In one embodiment, a photoresist spinner is used to get a uniform film on sample 104. A normal optical microscope is used to check for film quality. In a case where the film is not adequately coated, acetone is used to wash out the film and the film coating step is repeated. The film is then baked for approximately 15 minutes at approximately 130 degrees Celsius, and sample 104 is now ready for analysis.

At step 204, the present embodiment analyzes the sample for non-heat-related defects using a PEM processing method employed by single integrated FPEM system 100 of FIG. 1.

At step 206, the present embodiment analyzes the sample for heat-related defects using an FMI processing method employed by single integrated FPEM system 100 of FIG. 1. In so doing, the present invention allows users to perform fault isolation on both heat and non-heat related failures in one system, thereby saving time as compared to conventional separate fault detection systems.

Thus, the present invention provides a method and apparatus for performing failure analysis on an integrated circuit with submicron critical dimensions more efficiently. The present invention also provides a method and apparatus which achieve the above accomplishment and which can perform failure analysis for both heat-related and non-heat-related defects on an integrated circuit without requiring the use of multiple separate failure analysis systems. The present invention further provides a method and apparatus for performing failure analysis on an integrated circuit wherein the method and apparatus achieve the above accomplishments and do not result in the reduced throughput and accuracy associated with prior art approaches employing multiple separate conventional failure analysis systems.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications are suited to the particular use contemplated. It is intended that the scope of the invention be defined by the Claims appended hereto and their equivalents.

1. A single integrated fault detection apparatus for detecting heat-related and non-heat-related integrated circuit defects, said apparatus comprising:
a first portion for detecting said non-heat-related integrated circuit defects; and
a second portion for detecting said heat-related integrated circuit defects, said second portion integrated with said first portion to provide said single integrated fault detection apparatus such that said heat-related and said non-heat-related integrated circuit defects are detectable using only said single integrated fault detection apparatus.

2. The single integrated fault detection apparatus for detecting heat-related and non-heat-related integrated circuit defects of claim 1 wherein said first portion is adapted to perform photoemission microscopy (PEM) integrated circuit (IC) failure analysis.

3. The single integrated fault detection apparatus for detecting heat-related and non-heat-related integrated circuit defects of claim 1 wherein said second portion is adapted to perform fluorescent microthermal imaging (FMI) integrated circuit (IC) failure analysis.

4. A single integrated fault detection apparatus for detecting heat-related and non-heat-related integrated circuit defects, said apparatus comprising:
a switchable light source portion, said switchable light source portion adapted to selectively generate light of a desired wavelength for use in fault detection for a sample;
a optical inspection portion for detecting both heat-related and non-heat-related integrated circuit defects, said optical inspection portion optically coupled to said a switchable light source portion;
a controller portion coupled to said optical inspection portion for selectively controlling movement of said optical inspection portion; and
a monitoring portion for displaying said heat-related and non-heat-related integrated circuit defects, said monitoring portion coupled to said optical inspection portion, said single integrated fault detection apparatus configured such that both said heat-related and said non-heat-related integrated circuit defects are detectable using only said single integrated fault detection apparatus.

5. The single integrated fault detection apparatus for detecting heat-related and non-heat-related integrated circuit defects of claim 4 wherein said switchable light source portion comprises:
an ultraviolet light source;
a visible light source; and
selective switching devices coupled to said ultraviolet light source and said visible light source, said selective switching devices for selectively allowing transmission of said light of said desired wavelength therethrough.

6. The single integrated fault detection apparatus for detecting heat-related and non-heat-related integrated circuit defects of claim 4 wherein said single integrated fault detection apparatus is adapted to detect said non-heat-related integrated circuit defects using photoemission microscopy (PEM) integrated circuit (IC) failure analysis processes.

7. The single integrated fault detection apparatus for detecting heat-related and non-heat-related integrated circuit defects of claim 4 wherein said single integrated fault detection apparatus is adapted to detect said heat-related integrated circuit defects using fluorescent microthermal imaging (FMI) integrated circuit (IC) failure analysis processes.

8. A method for detecting heat-related and non-heat-related integrated circuit defects using a single integrated fault detection apparatus, said method comprising the steps of:
a) analyzing an integrated circuit for non-heat-related integrated circuit defects using a first portion of said single integrated fault detection apparatus; and
b) analyzing an integrated circuit for heat-related integrated circuit defects using a second portion of said single integrated fault detection apparatus such that said heat-related and said non-heat-related integrated circuit defects are detectable using only said single integrated fault detection apparatus.

9. The method for detecting heat-related and non-heat-related integrated circuit defects using a single integrated fault detection apparatus as recited in claim 8 wherein said step a) comprises:
analyzing an integrated circuit for non-heat-related integrated circuit defects using a photoemission microscopy (PEM) portion of said single integrated fault detection apparatus.

10. The method for detecting heat-related and non-heat-related integrated circuit defects using a single integrated fault detection apparatus as recited in claim 8 wherein said step b) comprises:
analyzing an integrated circuit for heat-related integrated circuit defects using a fluorescent microthermal imaging (FMI) portion of said single integrated fault detection apparatus.
